(19) United States
(12) Patent Application Publication
(10) Pub. No.: US 2024/0113031 A1
(43) Pub. Date: Apr. 4, 2024

(54) SEMICONDUCTOR PACKAGE STRUCTURE AND MANUFACTURING METHOD THEREFOR

(71) Applicant: Zhuhai ACCESS Semiconductor Co., LTD., Zhuhai City (CN)

(72) Inventors: Xianming CHEN, Zhuhai City (CN); Lei FENG, Zhuhai City (CN); Qiaoling LI, Zhuhai City (CN); Jun GAO, Zhuhai City (CN); Benxia HUANG, Zhuhai City (CN); Juchen HUANG, Zhuhai City (CN)

(73) Assignee: Zhuhai ACCESS Semiconductor Co., LTD., Zhuhai City (CN)

(21) Appl. No.: 18/465,889

(22) Filed: Sep. 12, 2023

(30) Foreign Application Priority Data
Sep. 29, 2022 (CN) 2022112015341

(51) Int. Cl. H01L 23/538; H01L 21/48; H01L 21/56; H01L 23/31; H01L 23/498

(52) U.S. Cl. CPC H01L 23/5383; H01L 21/4857; H01L 21/563; H01L 23/3128; H01L 23/49816; H01L 23/49894

(57) ABSTRACT

A semiconductor package structure and a manufacturing method therefor are disclosed. The semiconductor package structure includes a package layer, a first device layer, a first insulation layer, a conductive copper pillar, and a second device layer. The package layer covers the first device layer. The first device layer, the first insulation layer, and the second device layer are sequentially stacked. The conductive copper pillar extends through the first insulation layer. The first device layer and the second device layer are electrically connected through the conductive copper pillar. The first device layer includes a first circuit layer, a trench, and an embedded device. The embedded device is connected to the first circuit layer. The trench is arranged below the embedded device. The trench is partially or completely overlapped with a projection of the embedded device in a mounting direction of the embedded device.

### CROSS-REFERENCE TO RELATED APPLICATION

This application is based on and claims the benefit of priority from Chinese Patent Application No. 2022112015341, filed on 29 Sep. 2022, the entirety of which is incorporated by reference herein.

### TECHNICAL FIELD

The disclosure relates to the technical field of semiconductor, and in particular, to a semiconductor package structure and a manufacturing method therefor.

### BACKGROUND

With increasing development of electronic technologies, there is an increasingly high requirement on the performance of electronic products, resulting in increasingly complex circuits for electronic components and circuit board substrates. Meanwhile, the electronic products are required to have increasingly smaller and thinner sizes. Therefore, the integration, miniaturization, and multifunction of the circuits of electronic components and circuit board substrates are increasing. Reduction of the wire width and the distance between wires can greatly improve a wiring density of an entire layout. However, there will be a series of problems such as a decrease in the bonding force between a circuit and a base material, and a sharp increase in the short circuit between circuits along with the reduction of the distance. The substrate with embedded circuits has appeared correspondingly as a solution.

In the existing technology, when a device is packaged on a substrate, because the distance between pins of the device and the substrate is very small, the package material cannot be normally and completely filled to a bottom of the device, which leads to poor tightness between the pins of the device and poor electrical insulation, thereby affecting the service life of the device. Therefore, there is an urgent need for a novel semiconductor package structure.

### SUMMARY

An objective of the disclosure is to solve one of the problems in the existing technology at least to some extent.

Therefore, an objective of an embodiment of the disclosure is to provide a semiconductor package structure that can improve tightness of the device.

To achieve the foregoing objective, an embodiment of the disclosure provides a semiconductor package structure configured to connect to an external functional circuit, including: a package layer, a first device layer, a first insulation layer, a conductive copper pillar, and a second device layer; where the package layer covers the first device layer; the first device layer, the first insulation layer, and the second device layer are sequentially stacked; the conductive copper pillar extends through the first insulation layer; the first device layer and the second device layer are electrically connected through the conductive copper pillar; the first device layer includes a first circuit layer, a trench, and an embedded device; the embedded device is connected to the first circuit layer; the trench is arranged below the embedded device; the trench is partially or completely overlapped with a projection of the embedded device in a mounting direction of the embedded device; the second device layer includes a second circuit layer, a first solder mask layer, and a solder ball; the first solder mask layer partially covers the second circuit layer; and the solder ball is configured to implement an electrical connection between the second circuit layer and the external functional circuit.

In addition, based on the semiconductor package structure with the trench according to the foregoing embodiment of the disclosure, the following additional technical features may further be provided.

Further, in an embodiment of the disclosure, the first device layer further includes a second solder mask layer; and the second solder mask layer partially covers the first circuit layer.

Further, in an embodiment of the disclosure, the first insulation layer includes a Polypropylene (PP) material or an Aromatic Benzocyclobutene Film (ABF) material.

Further, in an embodiment of the disclosure, a quantity of the embedded device is one or more; and a quantity of the trench is one or more.

Further, in an embodiment of the disclosure, the embedded device includes an active device or a passive device.

Further, in an embodiment of the disclosure, a depth of the trench is greater than or equal to a thickness of the first circuit layer.

In addition, an embodiment of the disclosure further provides a manufacturing method for the semiconductor package structure according to any one of the foregoing embodiments, including: preparing a temporary carrier plate, where the temporary carrier plate includes a first metal layer and a bearing plate, and the first metal layer and the bearing plate are stacked; manufacturing the first circuit layer by taking the first metal layer as a base material; laminating the first insulation layer on the first circuit layer to enable the first insulation layer to cover the first circuit layer; manufacturing the conductive copper pillar and the second circuit layer on the first insulation layer; removing the bearing plate, and manufacturing the trench on the first circuit layer; mounting the embedded device, where the embedded device is partially or completely overlapped with the projection of the trench in the mounting direction of the embedded device; soldering the solder ball on the second circuit layer and manufacturing the first solder mask layer, where the first solder mask layer partially covers the second circuit layer; and covering a package material on the first circuit layer, the embedded device, and the trench.

Further, in an embodiment of the disclosure, manufacturing the first circuit layer by taking the first metal layer as a base material includes: applying a first photoresist layer on the first metal layer; performing an exposure and development process on the first photoresist layer to obtain a first circuit pattern; and performing an etching process on the first circuit pattern to obtain the first circuit layer.

Further, in an embodiment of the disclosure, manufacturing the conductive copper pillar and the second circuit layer on the first insulation layer includes: drilling the first insulation layer to form a non-plating through-hole, where the non-plating through-hole extends through the first insulation layer to enable the first circuit layer to be exposed; filling and electroplating the non-plating through-hole to form the conductive copper pillar and a second metal seed layer; applying a second photoresist layer on the second metal seed layer; performing an exposure and development process on the second photoresist layer to obtain a second circuit pattern; and performing an etching process on the second circuit pattern to obtain the second circuit layer.

Further, in an embodiment of the disclosure, manufacturing the trench on the first circuit layer includes: applying a third photoresist layer on a lower surface of the first circuit layer, where the lower surface is a surface opposite to a surface of the first circuit layer laminated with the first insulation layer; performing an exposure and development process on the third photoresist layer to obtain a third circuit pattern; and performing an etching process on the third circuit pattern to obtain the trench.

Further, in an embodiment of the disclosure, applying a first photoresist layer on the first metal layer includes: applying the first photoresist layer on the first metal layer in a film-bonding or coating mode.

In addition, the disclosure further provides an integrated circuit system including at least one semiconductor package structure according to any one of the foregoing embodiments.

The advantages and beneficial effects of the disclosure will be partially set forth in the following description, some of which will be apparent from the following description, or will be learned by practice of the disclosure.

According to the package structure of the disclosure, the trench is arranged below the embedded device, so that a package material can completely permeate into a space below the pins of the embedded device when the embedded device is subjected to a packaging process, and the package material are filled between the pins of the embedded device, therefore, the complete sealing for the pins is realized, the tightness of the device can be improved, the electrical insulation between the pins can be realized, and the service life of the whole package structure can be prolonged.

### BRIEF DESCRIPTION OF DRAWINGS

FIG. 1 is a schematic diagram of a semiconductor package structure according to an embodiment of the disclosure;

FIG. 2 is a schematic flowchart of a manufacturing method for a semiconductor package structure according to an embodiment of the disclosure;

FIG. 3 is a schematic diagram of structural changes during the manufacturing process for a semiconductor package structure according to an embodiment of the disclosure; and

FIG. 4 is a schematic diagram of a semiconductor package structure in a conventional process according to an embodiment of the disclosure.

### DETAILED DESCRIPTION

The principles and processes of a semiconductor package structure, and a manufacturing method therefor according to embodiments of the disclosure are described in detail below with reference to the accompanying drawings.

First, the defects of the conventional packaging process will be described with reference to the accompanying drawings.

Referring to FIG. 4, it can be seen from FIG. 4 that, in the conventional process, when an embedded device is packaged, because a gap between pins of the embedded device and a device body is very small, a package material cannot normally enter a lower part of the embedded device, and the material cannot completely wrap the embedded device. Therefore, in the existing process, a gap is often formed below the embedded device, resulting in poor tightness of the embedded device. Water vapor, oxygen or other gases capable of etching the device are likely to exist in the gap, and existence of these gases in the gap for a long time will accelerate the aging of the device, reduce the life of the device, thus affecting the product quality.

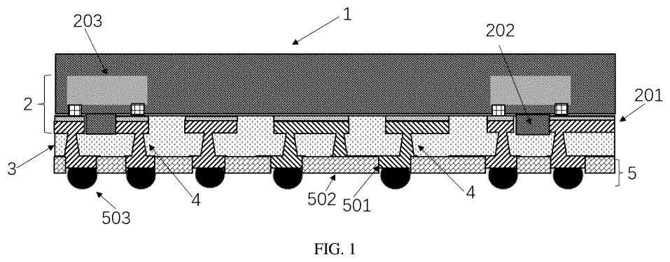

Based on the foregoing defects, referring to FIG. 1, the disclosure provides a novel semiconductor package structure that may be connected to an external functional circuit. The external functional circuit may be another semiconductor structure, or another integrated circuit, or an active device or a passive device, or a circuit on a PCB. The semiconductor package structure may include: a package layer 1, a first device layer 2, a first insulation layer 3, a conductive copper pillar 4, and a second device layer 5. The package layer 1 may cover the first device layer 2. The first device layer 2, the first insulation layer 3, and the second device layer 5 may be sequentially stacked. The conductive copper pillar 4 may extend through the first insulation layer 3. The first device layer 2 and the second device layer 5 are electrically connected through the conductive copper pillar 4. The first device layer 2 may include a first circuit layer 201, a trench 202, and an embedded device 203. The first circuit layer 201 may be a circuit layer connected to the embedded device 203. The embedded device 203 may be connected to the first circuit layer 201 through a pin or a pad. The trench 202 may be arranged below the embedded device 203. The trench 202 may be partially or completely overlapped with a projection of the embedded device 203 in a mounting direction of the embedded device 203. The second device layer 5 may include a second circuit layer 501, a first solder mask layer 502, and a solder ball 503. The second circuit layer 501 is a circuit layer that may be connected to the solder ball 503 and to the first circuit layer 501 through the conductive copper pillar 4. The first solder mask layer 502 may partially cover the second circuit layer 501, so that a part of position in the second circuit layer 501 may be connected to the solder ball 503. The solder ball 503 may implement an electrical connection between the second circuit layer 501 and the external functional circuit.

Further, in some embodiments of the disclosure, the first device layer may further include a second solder mask layer. The second solder mask layer may partially cover the first circuit layer, and the partial covering may be covering all other areas of the first circuit layer except for an area that requires to connect to the embedded device, or a specific area in the first circuit layer, where the specific area may be an area requiring corrosion protection. The second solder mask layer can prevent partial areas of the first circuit layer from being oxidized or etched when the embedded device is mounted or the structure is packaged.

Further, in some embodiments of the disclosure, the first insulation layer may include a PP (Polypropylene) material or an ABF (Aromatic Benzocyclobutene Film) material, where the PP material and the ABF material have a good insulating property, good corrosion resistance, and no toxicity, which is appliable to an insulation layer of a semiconductor. It should be noted that the first insulation layer may also be an insulation layer made of other existing or future generated insulating materials, or an insulation layer made of a mixture of PP, ABF and other insulation layers. Specifically, the mixture may be a mixture of materials, or a physical laminate of layers made of different materials. For example, a PP material may form one sub-insulation layer, and then an ABF material may form another sub-insulation layer, and the two sub-insulation layers are laminated to form the corresponding first insulation layer.

Further, in some embodiments of the disclosure, there may be one or more embedded devices, and one or more trenches which are in one-to-one correspondence with the embedded devices. In a semiconductor structure, there are usually more than one embedded device, and the trenches may also be arranged in one-to-one correspondence with the embedded devices. The trenches in one-to-one correspondence with the embedded devices may enable the space below the pins of each embedded device to be filled with the package material, thus improving the tightness of the entire structure, reducing damage to the embedded devices due to the static electricity and other impurities in the air, and prolonging the service life of the embedded devices.

Further, in some embodiments of the disclosure, the embedded device may include an active device or a passive device, where the active device may be a triode, a MOS transistor, other transistors, a chip, or other small integrated circuits, and the passive device may be a resistor, a capacitor, or other passive devices.

Further, in some embodiments of the disclosure, a depth of the trench may be greater than or equal to a depth of the first circuit layer. The trench may implement penetration of the package material to enable the package material to cover and wrap the entire embedded device, and may also implement electrical isolation on some areas of the first circuit layer. Therefore, the depth of the trench may be greater than or equal to the thickness of the first circuit layer, which may implement electrical isolation on some areas of the first circuit layer.

Further, in some embodiments of the disclosure, the material of the solder ball may include at least one of gold, copper, or tin. The solder ball may be made of one of a copper material, a tin material, or an alloy material, and may also be made of two or three of the foregoing three materials. The three materials may have good conductivity and are easily available, which can improve the practicability of the device. Gold has better corrosion resistance, while tin and copper are cheaper than gold, and the material cost can be reduced by using copper or tin.

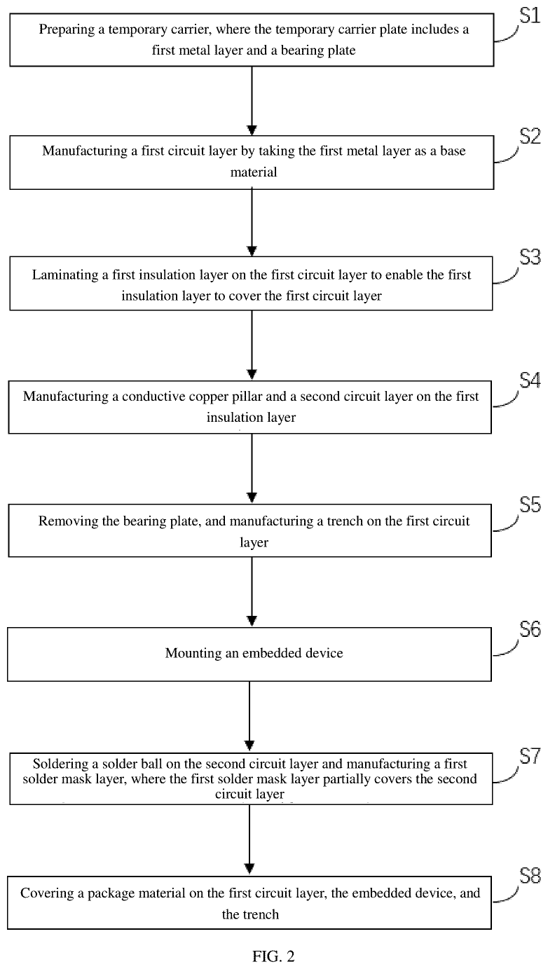

In addition, referring to FIG. 2, corresponding to the structure of FIG. 1, an embodiment of the disclosure further provides a manufacturing method for a semiconductor package structure, which may be used to manufacture the semiconductor package structure according to any one of the foregoing embodiments and may include:

S1: preparing a temporary carrier, where the temporary carrier plate includes a first metal layer and a bearing plate.

In some embodiments of the disclosure, the temporary carrier plate may include a first metal layer and a bearing plate. A thickness of the first metal layer may conform to a thickness of a circuit layer to be manufactured, and the bearing plate may be a common insulating bearing plate or a bearing plate formed by laminating different thin layers made of different materials. The first metal layer and the bearing plate may be stacked, and physical or chemical separation can be performed in a subsequent process, where the physical separation may be machine tearing separation or machine grinding separation, and the chemical separation is to etch the material of the bearing plate through a chemical agent. When the bearing plate is formed by laminating a plurality of thin layers made of different materials, the bearing plate can be removed by etching the corresponding material through a plurality of agents.

S2: manufacturing a first circuit layer by taking the first metal layer as a base material. In some embodiments of the disclosure, the first metal layer may be used as a base material for manufacturing the first circuit layer, the first metal layer may be manufactured into a circuit layer capable of implementing functions or electrical signal transmission through processes such as exposure, development, and etching, and the first circuit layer may be subsequently used for mounting and embedding an embedded device. It should be noted that, because the thicknesses of different circuit layers may be different, in the process of manufacturing the first circuit layer, the first metal layer may also be thinned or thickened to meet the thickness requirement of circuit manufacturing.

S3: laminating a first insulation layer on the first circuit layer to enable the first insulation layer to cover the first circuit layer.

In some embodiments of the disclosure, when the first insulation layer is laminated on the first circuit layer, the first insulation layer needs to completely cover the first circuit layer, so as to prevent the first circuit layer from generating a gap, which affects the tightness of the first circuit layer, and thus affects the function implementation and the service life of the circuit layer.

S4: manufacturing a conductive copper pillar and a second circuit layer on the first insulation layer.

In some embodiments of the disclosure, it is necessary to manufacture a conductive copper pillar and a second circuit layer on the first insulation layer. The conductive copper pillar may implement the electrical or signal connection of the first circuit layer and the second circuit layer, where the second circuit layer may be a circuit layer connected to the first circuit layer and to an external functional circuit in a subsequent process, and the second circuit layer may be a functional circuit layer or a conductive circuit layer.

S5: removing the bearing plate, and manufacturing a trench on the first circuit layer.

In some embodiments of the disclosure, the bearing plate may be removed first, and the bearing plate may be removed through chemical corrosion or physical tearing. After the bearing plate is removed, a trench may be manufactured from a surface of the first circuit layer opposite to the surface covered with the first insulation layer. A photoresist layer may be applied to a lower surface of the first circuit layer, where the lower surface may be a surface opposite to the surface where the first circuit layer and the first insulation layer are laminated, the trench is finally obtained through exposure, development and etching processes, and the trench may be arranged between different areas of the first circuit layer. The trench may not only make the package material fill a space below the embedded device, but also implement the electrical isolation of some areas of the first circuit layer. S6: mounting an embedded device.

In some embodiments of the disclosure, mounting the embedded device may be that the embedded device is partially or completely overlapped with a projection of the trench in a mounting direction of the embedded device. When the pins of the embedded device face downward, the trench may be directly below the embedded device or below a side of the embedded device, and the trench is partially overlapped with a projection of the embedded device in a vertical direction.

S7: soldering a solder ball on the second circuit layer and manufacturing a first solder mask layer, where the first solder mask layer partially covers the second circuit layer.

In some embodiments of the disclosure, a solder ball may be soldered on the second circuit layer, and a solder mask layer may be manufactured. Two or more solder balls may be soldered, a position of the first solder mask layer may be other areas in the second circuit layer where no solder balls are soldered, and the first solder mask layer partially covering the second circuit layer can improve the corrosion resistance of partial areas in the second circuit layer without hindering the connection between the solder balls and external functional circuits.

S8: covering a package material on the first circuit layer, the embedded device, and the trench.

In some embodiments of the disclosure, a package material is covered on the first circuit layer, the embedded device, and the trench. The package material needs to completely cover and wrap the first circuit layer and the embedded device. The trench is filled and covered by the package material, and because the trench and the embedded device are partially or completely overlapped in a direction perpendicular to a horizontal plane, when the package material is covered, the package material can permeate into a lower part of the embedded device through the trench to fill the gap between the pins below the embedded device and the circuit layer, so that the pins below the embedded device are completely sealed, avoiding damage to the circuit layer or the pins due to static electricity, moisture and the like in the air which will affect the service life of the device and the circuit layer.

Further, the manufacturing a first circuit layer by taking the first metal layer as a base material may include:

S11: applying a first photoresist layer on the first metal layer;

S12: performing an exposure and development process on the first photoresist layer to obtain a first circuit pattern; and

S13: performing an etching process on the first circuit pattern to obtain a first circuit layer.

In some embodiments of the disclosure, the first circuit layer is manufactured by the following steps. Firstly, a first photoresist layer covers the first metal layer, and then the first photoresist layer is subjected to exposure and development to obtain a first circuit pattern, where the first circuit pattern may protect a part of the first metal layer that does not need to be etched, and may expose a part that needs to be etched, the part that needs to be etched is etched and removed through chemical etching, then an etching solution and the residual unexposed photoresist layer are removed through an alkaline solution, and finally the first circuit layer is obtained. The chemical etching may remove metals using an acidic etching reagent, such as an acidic ferric chloride reagent, and the alkaline solution for removing may be a sodium hydroxide solution.

Further, the manufacturing a conductive copper pillar and a second circuit layer on the first insulation layer may include:

S21: drilling the first insulation layer to form a non-plating through-hole, where the non-plating through-hole extends through the first insulation layer to enable the first circuit layer to be exposed;

S22: filling and electroplating the non-plating through-hole to form the conductive copper pillar and a second metal seed layer;

S23: applying a second photoresist layer on the second metal seed layer;

S24: performing an exposure and development process on the second photoresist layer to obtain a second circuit pattern; and

S25: performing an etching process on the second circuit pattern to obtain a second circuit layer.

In some embodiments of the disclosure, the first insulation layer may be subjected to laser or other drilling methods to form a non-plating through-hole, where there may be one or more non-plating through-holes, and the specific quantity of the non-plating through-holes may be determined based on requirement of the circuit. The non-plating through-hole may extend through the first insulation layer, so that the first circuit layer is exposed through an opening. The non-plating through-hole is filled and electroplated, where in the hole filling and electroplating process, a copper foil may be firstly deposited on a side wall of the non-plating through-hole to gradually fill the entire non-plating through-hole, and then a second metal seed layer that may be used for manufacturing a circuit layer may be formed on the first insulation layer by continuing electroplating. A second photoresist material is applied on the second metal seed layer, where the second photoresist material may completely cover the second metal seed layer. Then the second photoresist material is subjected to exposure and development to obtain a second circuit pattern, where the second circuit pattern may shield a part of the metal seed layer that does not need to be etched to avoid being etched by the etching solution, and may expose a part of the metal seed layer that needs to be etched, so as to facilitate the subsequent etching process. Finally, the second circuit pattern is etched by using an acidic etching solution to remove part of the metal seed layer, then the etching solution and the unexposed photoresist material are removed by using an alkaline solution, and finally the alkaline solution is removed by washing to obtain a final second circuit layer.

Further, the manufacturing a trench on the first circuit layer may include:

S31: applying a third photoresist layer on a lower surface of the first circuit layer, where the lower surface is a surface opposite to a surface of the first circuit layer laminated with the first insulation layer;

S32: performing an exposure and development process on the third photoresist layer to obtain a third circuit pattern; and

S33: performing an etching process on the third circuit pattern to obtain the trench.

In some embodiments of the disclosure, since the bearing plate is physically or chemically removed before the trench is manufactured, a third photoresist material may be applied to a lower surface of the first circuit layer, where the lower surface may be a surface opposite to a surface of the first circuit layer laminated with the first insulation layer. Then the third photoresist material is subjected to exposure and development to obtain a third circuit pattern, where the third circuit pattern may protect some circuits of the first circuit layer and expose the trench area. Finally, the third circuit layer is etched, and the etching solution and the alkaline solution are removed to obtain a trench, where the trench may facilitate the penetration of the package material into the bottom of the embedded device, and may implement the electrical isolation of some areas of the first circuit layer.

Further, the applying a first photoresist layer on the first metal layer may include: applying the first photoresist layer on the first metal layer in a film-bonding or coating mode. The photoresist layer may be applied on the first metal layer in a coating or film-bonding mode, and the specific application mode is not limited. It should be noted that the photoresist layer in all embodiments of the disclosure may be applied in the film-bonding or coating method.

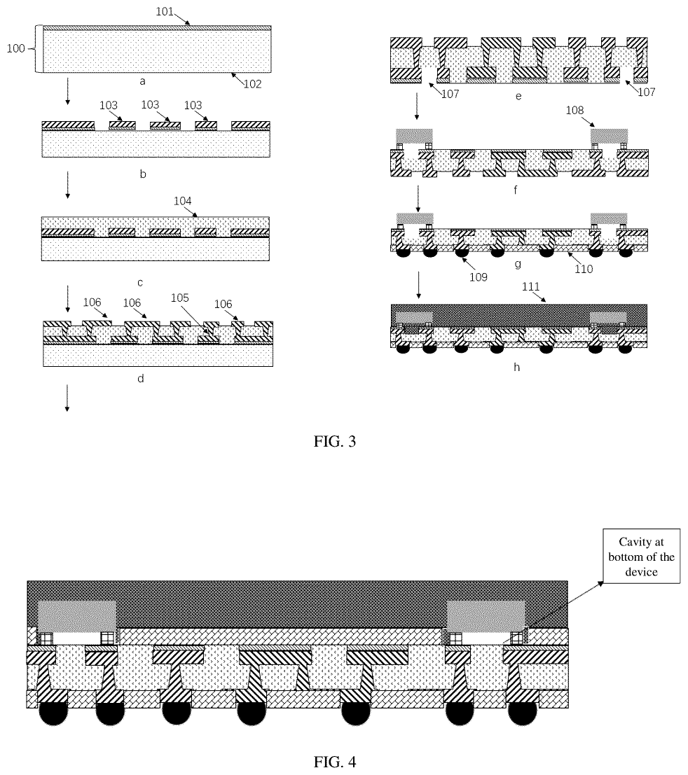

The following describes a manufacturing process of the semiconductor package structure according to the disclosure with reference to FIG. 3.

First, referring to a in FIG. 3, a temporary carrier plate 100 is prepared, where the temporary carrier plate 100 includes a first metal layer 101 and a bearing plate 102.

Second, referring to b in FIG. 3, a first circuit layer 103 is manufactured on the first metal layer 101. The first circuit layer 103 is obtained by the common manufacturing processes, namely, performing photoresist application, exposure, development, and etching processes on the first metal layer 101.

Then, referring to c in FIG. 3, a first insulation layer 104 is laminated on the first circuit layer 103 through a machine, so that the first insulation layer 104 completely covers the first circuit layer 103.

Then, referring to d in FIG. 3, a conductive copper pillar 105 and a second circuit layer 106 are manufactured on the first insulation layer 104 by drilling and electroplating processes, where the drilling process may be a laser drilling process.

Then, referring to e in FIG. 3, the bearing plate 102 is removed, and a trench 107 is manufactured on the first circuit layer 102. During manufacturing, a photoresist may be applied on a bottom surface of the first circuit layer 103, and the trench 107 is obtained through exposure, development, and etching processes.

In addition, referring to fin FIG. 3, an embedded device 108 is mounted on the first circuit layer 103, and the embedded device 108 is completely overlapped with a projection of the trench 107 in a mounting direction of the embedded device 108.

Next, referring to g in FIG. 3, a solder ball 109 is soldered on the second circuit layer 106 and a first solder mask layer 110 is manufactured, where the first solder mask layer 110 partially covers the second circuit layer 106.

Finally, referring to h in FIG. 3, a package material 111 is covered on the first circuit layer 103, the embedded device 108, and the trench 107, so that the package material 111 completely wraps and covers the first circuit layer 103, the embedded device 108, and the trench 107.

In addition, corresponding to the semiconductor package structure of FIG. 1, an embodiment of the disclosure further provides an integrated circuit system. The integrated system may include at least one semiconductor package structure according to any of the foregoing embodiments. The semiconductor package structure according to the disclosure is provided with the solder ball, so that the semiconductor package structure can be connected to other devices or integrated circuits, to form an integrated circuit system. The integrated circuit system has good tightness and corrosion resistance.

In some optional embodiments, the functions/operations mentioned in the block diagrams may occur out of the order mentioned in the operational diagrams. For example, two blocks shown in succession may, in fact, be executed substantially concurrently, or the blocks may sometimes be executed in a reverse order, depending upon the functionality/operations involved. In addition, the embodiments presented and described in the flowcharts of the disclosure are provided by way of example in order to provide a more comprehensive understanding of this technology. The disclosed methods are not limited to the operations and logic flows presented herein. Optional embodiments are contemplated in which the order of various operations is changed, and in which sub-operations described as part of larger operations are performed independently.

In the foregoing description of this specification, the description with reference to the terms “an implementation/embodiment”, “another implementation/embodiment”, “some implementations/embodiments”, or the like means the specific features, structures, materials, or characteristics described in combination with the embodiment or example are included in at least one embodiment or example of the disclosure. In this specification, the schematic expression of the foregoing terms does not necessarily refer to the same embodiment or example. Furthermore, the specific features, structures, materials, or characteristics described can be combined in any suitable manner in any one or more embodiments or examples.

Although the embodiments of the disclosure have been shown and described, it may be understood by those of ordinary skill in the art that various changes, modifications, substitutions, and alterations may be made to these embodiments without departing from the principle and purpose of the disclosure, and the scope of the disclosure is defined in the claims and equivalents thereof.

The foregoing describes the preferred embodiments of the disclosure in detail, however, the disclosure is not limited to the embodiments. Those of ordinary skills in the art can make various equivalent changes or substitutions without departing from the gist of the disclosure, and such equivalent changes or substitutions are all included in the scope defined by the claims of the disclosure.

What is claimed is:

1. A semiconductor package structure configured to connect to an external functional circuit, comprising:
a package layer, a first device layer, a first insulation layer, a conductive copper pillar, and a second device layer; wherein the package layer covers the first device layer; the first device layer, the first insulation layer, and the second device layer are sequentially stacked; the conductive copper pillar extends through the first insulation layer; the first device layer and the second device layer are electrically connected through the conductive copper pillar;
wherein the first device layer comprises a first circuit layer, a trench, and an embedded device; the embedded device is connected to the first circuit layer; the trench is arranged below the embedded device; the trench is partially or completely overlapped with a projection of the embedded device in a mounting direction of the embedded device; and
wherein the second device layer comprises a second circuit layer, a first solder mask layer, and a solder ball; the first solder mask layer partially covers the second circuit layer; and the solder ball is configured to implement an electrical connection between the second circuit layer and the external functional circuit.

2. The semiconductor package structure according to claim 1, wherein the first device layer further comprises a second solder mask layer; and the second solder mask layer partially covers the first circuit layer.

3. The semiconductor package structure according to claim 1, wherein the first insulation layer comprises a Polypropylene (PP) material or an Aromatic Benzocyclobutene Film (ABF) material.

4. The semiconductor package structure according to claim 1, wherein a quantity of the embedded device is one or more; and a quantity of the trench is one or more.

5. The semiconductor package structure according to claim 1, wherein the embedded device comprises an active device or a passive device.

6. The semiconductor package structure according to claim 1, wherein a depth of the trench is greater than or equal to a thickness of the first circuit layer.

7. A manufacturing method for the semiconductor package structure according to claim 1, comprising:
preparing a temporary carrier plate, wherein the temporary carrier plate comprises a first metal layer and a bearing plate, and the first metal layer and the bearing plate are stacked;
manufacturing the first circuit layer by taking the first metal layer as a base material;
laminating the first insulation layer on the first circuit layer to enable the first insulation layer to cover the first circuit layer;
manufacturing the conductive copper pillar and the second circuit layer on the first insulation layer;
removing the bearing plate, and manufacturing the trench on the first circuit layer;
mounting the embedded device, wherein the embedded device is partially or completely overlapped with the projection of the trench in the mounting direction of the embedded device;
soldering the solder ball on the second circuit layer and manufacturing the first solder mask layer, wherein the first solder mask layer partially covers the second circuit layer; and
covering a package material on the first circuit layer, the embedded device, and the trench.

8. The manufacturing method according to claim 7, wherein the manufacturing the first circuit layer by taking the first metal layer as a base material comprises:
applying a first photoresist layer on the first metal layer;
performing an exposure and development process on the first photoresist layer to obtain a first circuit pattern; and
performing an etching process on the first circuit pattern to obtain the first circuit layer.

9. The manufacturing method for a semiconductor package structure according to claim 7, wherein the manufacturing the conductive copper pillar and the second circuit layer on the first insulation layer comprises:
drilling the first insulation layer to form a non-plating through-hole, wherein the non-plating through-hole extends through the first insulation layer to enable the first circuit layer to be exposed;
filling and electroplating the non-plating through-hole to form the conductive copper pillar and a second metal seed layer;
applying a second photoresist layer on the second metal seed layer;
performing an exposure and development process on the second photoresist layer to obtain a second circuit pattern; and
performing an etching process on the second circuit pattern to obtain the second circuit layer.

10. The manufacturing method according to claim 8, wherein the manufacturing the trench on the first circuit layer comprises:
applying a third photoresist layer on a lower surface of the first circuit layer, wherein the lower surface is a surface opposite to a surface of the first circuit layer laminated with the first insulation layer;
performing an exposure and development process on the third photoresist layer to obtain a third circuit pattern; and
performing an etching process on the third circuit pattern to obtain the trench.

11. The manufacturing method according to claim 8, wherein the applying a first photoresist layer on the first metal layer comprises:
applying the first photoresist layer on the first metal layer in a film-bonding or coating mode.

12. An integrated circuit system, comprising at least one semiconductor package structure according to claim 1.
